(19) United States
(12) Patent Application Publication
(10) Pub. No.: US 2025/0095735 A1
(43) Pub. Date: Mar. 20, 2025

(54) INTEGRATED CIRCUIT INCLUDING TERNARY CONTENT ADDRESSABLE MEMORY CELL

(71) Applicant: SAMSUNG ELECTRONICS CO., LTD., Suwon-si (KR)

(72) Inventors: Jinmyeong Hong, Suwon-si (KR); Suk Youn, Suwon-si (KR); Taehyung Kim, Suwon-si (KR); Hoyoung Tang, Suwon-si (KR)

(21) Appl. No.: 18/664,549

(22) Filed: May 15, 2024

(30) Foreign Application Priority Data
Sep. 19, 2023 (KR) 10-2023-0125004

(51) Int. Cl. G11C 15/04

(52) U.S. Cl. CPC G11C 15/04

(57) ABSTRACT

An example integrated circuit includes a ternary content-addressable memory (TCAM) cell on a front side of a substrate, a backside via extending through the substrate in a vertical direction with respect to the substrate, a backside wiring layer on a back side of the substrate, and a frontside wiring layer above the TCAM cell in the vertical direction. The TCAM cell includes a first cell storing a first value, a second cell storing a second value, and a comparison circuit connected with the first and second cells. The backside wiring layer includes at least one backside power rail configured to transmit a supply voltage to the TCAM cell through the backside via. The frontside wiring layer includes a bit line connected with the first and second cells, a complementary bit line connected with the first and second cells, and a match line connected with the comparison circuit.

### CROSS-REFERENCE TO RELATED APPLICATION

This application claims priority under 35 U.S.C. § 119 to Korean Patent Application No. 10-2023-0125004, filed on Sep. 19, 2023, in the Korean Intellectual Property Office, the disclosure of which is incorporated by reference herein in its entirety.

### BACKGROUND

Due to the demand for high integration and the development of semiconductor processes, the width, spacing, and/or height of wirings included in integrated circuits may decrease, and the influence of parasitic components of wirings may increase. In addition, the power voltage of integrated circuits may decrease for reduced power consumption, high operating speed, etc., and accordingly, the parasitic components of wirings may have a more significant impact on integrated circuits. Therefore, there is increasing demand for a design method for integrated circuits that efficiently routes wires and vias.

### SUMMARY

The present disclosure relates to an integrated circuit capable of improving Power Performance Area (PPA) by implementing the integrated circuit including a ternary content-addressable memory (TCAM) cell by using backside wirings.

In some implementations, an integrated circuit includes a Ternary Content Addressable Memory (TCAM) cell arranged on a front side of a substrate, and including a first cell storing a first value, a second cell storing a second value, and a comparison circuit connected to the first and second cells, a backside via penetrating the substrate in a vertical direction with respect to the substrate, a backside wiring layer arranged on a back side of the substrate and including at least one backside power rail configured to transmit a supply voltage to the TCAM cell through the backside via, and a frontside wiring layer arranged above the TCAM cell in the vertical direction, and including a bit line connected to the first and second cells, a complementary bit line connected to the first and second cells, and a match line connected to the comparison circuit.

In some implementations, an integrated circuit includes a Ternary Content Addressable Memory (TCAM) cell arranged on a front side of a substrate, and including a first cell storing a first value, a second cell storing a second value, and a comparison circuit connected to the first and second cells, a backside via penetrating the substrate in a vertical direction with respect to the substrate, a backside wiring layer arranged on the back side of the substrate and including a match line connected to the comparison circuit through the backside via, and a frontside wiring layer arranged above the TCAM cell in the vertical direction, and including a bit line connected to the first and second cells, a complementary bit line connected to the first and second cells, and at least one frontside power rail configured to transmit a supply voltage to the TCAM cell.

In some implementations, an integrated circuit includes a Ternary Content Addressable Memory (TCAM) cell arranged on a front side of a substrate, and including a first cell storing a first value, a second cell storing a second value, and a comparison circuit connected to the first and second cells, a backside via penetrating the substrate in a vertical direction with respect to the substrate, a backside wiring layer arranged on the back side of the substrate and including at least one word line connected to the first and second cells through the backside via, and a frontside wiring layer arranged above the TCAM cell in the vertical direction, and including a bit line connected to the first and second cells, a complementary bit line connected to the first and second cells, and at least one frontside power rail configured to transmit a supply voltage to the TCAM cell.

### BRIEF DESCRIPTION OF THE DRAWINGS

Implementations of the present disclosure will be more clearly understood from the following detailed description taken in conjunction with the accompanying drawings.

FIG. 1 is a circuit diagram illustrating an example of a memory cell.

FIG. 2 is a layout diagram illustrating an example of an integrated circuit including the memory cell of FIG. 1.

FIG. 3A is a plan view illustrating an example of a backside wiring layer of the integrated circuit of FIG. 2, FIG. 3B is a plan view illustrating an example of a first frontside wiring layer of the integrated circuit of FIG. 2, and FIG. 3C is a plan view illustrating an example of a second frontside wiring layer of the integrated circuit of FIG. 2.

FIG. 4A is an example cross-sectional view taken along line I-I′ of FIG. 2, and FIG. 4B is an example cross-sectional view taken along line II-II′ of FIG. 2.

FIG. 5 is a layout diagram illustrating an example of an integrated circuit including the memory cell of FIG. 1.

FIG. 6A is a plan view illustrating an example of a backside wiring layer of the integrated circuit of FIG. 5, FIG. 6B is a plan view illustrating an example of a first frontside wiring layer of the integrated circuit of FIG. 5, and FIG. 6C is a plan view illustrating an example of a second frontside wiring layer of the integrated circuit of FIG. 5.

FIG. 7A is an example cross-sectional view taken along line III-III′ of FIG. 5, FIG. 7B is an example cross-sectional view taken along line IV-IV′ of FIG. 5, and FIG. 7C is an example cross-sectional view taken along line V-V′ of FIG. 5.

FIG. 8 is a layout diagram illustrating an example of an integrated circuit including the memory cell of FIG. 1.

FIG. 9A is a plan view illustrating an example of a backside wiring layer of the integrated circuit of FIG. 8, FIG. 9B is a plan view illustrating an example of a first frontside wiring layer of the integrated circuit of FIG. 8, and FIG. 9C is a plan view illustrating an example of a second frontside wiring layer of the integrated circuit of FIG. 8.

FIG. 10A is an example cross-sectional view taken along line VI-VI′ of FIG. 8, and FIG. 10B is an example cross-sectional view taken along line VII-VII′ of FIG. 8.

FIG. 11 is a block diagram illustrating an example of a memory device.

FIGS. 12A to 12D are diagrams illustrating an example of an element.

FIG. 13 is a flowchart illustrating an example of a method of manufacturing an integrated circuit.

FIG. 14 is a block diagram illustrating an example of a system-on-chip.

FIG. 15 is a block diagram illustrating an example of a computing system including a memory for storing a program.

### DETAILED DESCRIPTION

Hereinafter, implementations of the present disclosure will be described in detail with reference to the accompanying drawings. The same reference numerals are used for the same components in the drawings, and redundant descriptions thereof will be omitted.

In the present specification, an X-axis direction may be referred to as a first horizontal direction or a first direction, a Y-axis direction may be referred to as a second horizontal direction or a second direction, and a Z-axis direction may be referred to as a vertical direction. A plane consisting of X and Y axes may be referred to as a horizontal plane, a component arranged in the +Z axis direction relative to another component may be referred to as being above another component, and a component arranged in the −Z axis direction relative to another component may be referred to as being below another component.

An integrated circuit may be designed by arranging a plurality of standard cells. A standard cell may be referred to as a unit of a layout of an integrated circuit, and may be referred to as a cell. The standard cell may be designed to include a plurality of transistors to perform a predefined function. This standard cell method is a method of preparing standard cells with multiple functions in advance and combining the standard cells to design a dedicated large-scale integrated circuit tailored to the specifications of customers or users. Standard cells are designed and verified in advance and registered in a standard cell library, and integrated circuits may be designed by performing logical design, placement, and routing that combine standard cells using Computer Aided Design (CAD). When designing these integrated circuits, the performance of integrated circuits may be further improved by reducing the length and routing complexity of wirings and/or vias.

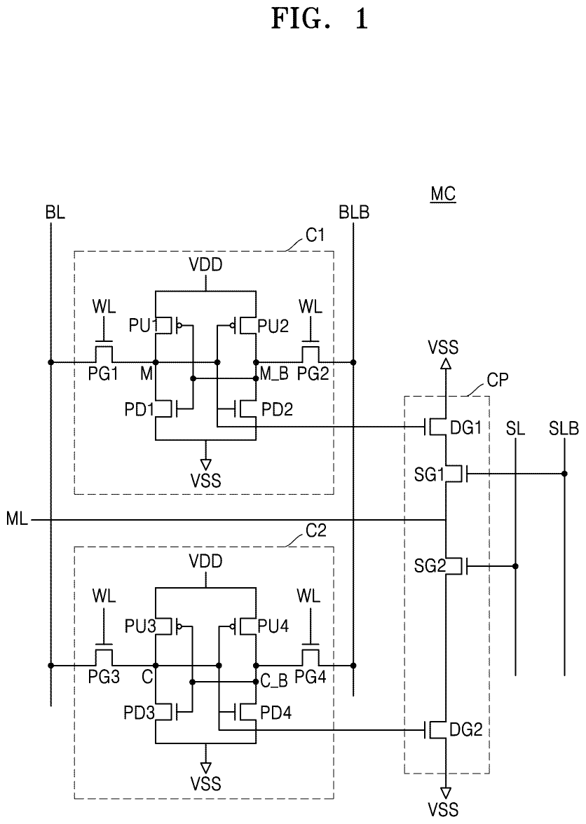

FIG. 1 is a circuit diagram illustrating an example of a memory cell MC.

Referring to FIG. 1, a memory cell MC may be connected to a word line WL, a bit line BL, and a complementary bit line BLB, and may also be connected to a match line ML, a search line SL, and a complementary search line SLB. In some implementations, the memory cell MC may correspond to a ternary content addressable memory (TCAM) cell. TCAM cells are widely used in applications that require very fast search on databases, such as networking, imaging, and voice recognition. Hereinafter, the memory cell MC will be referred to as a TCAM cell.

The memory cells MC may include a first cell C1, a second cell C2, and a comparison circuit CP. As the first cell C1 stores a first value and the second cell C2 stores a second value, the first cell C1 and the second cell C2 may constitute a storage circuit for storing three values of “0”, “1”, and “x” (don't care). For example, when the first value is 1 and the second value is 0, it may be considered that the memory cell MC stores “0”. For example, when the first value is 0 and the second value is 1, it may be considered that the memory cell MC stores “1”. For example, when the first value is 1 and the second value is 1, it may be considered that the memory cell MC stores “x”.

In some implementations, the first cell C1 may be referred to as a mask cell, and the second cell C2 may be referred to as a content cell or a key cell. For example, each of the first cell C1 and the second cell C2 may be implemented as a static random access memory (SRAM) cell. The comparison circuit CP may be connected to the first cell C1 and the second cell C2, and may be cascaded to the storage circuit. Hereinafter, the configuration of the memory cell MC will be described in more detail.

The first cell C1 may include a cross-coupled inverter pair between a node to which a positive supply voltage, for example, a power supply voltage VDD is applied and a node to which a negative supply voltage, for example, a ground voltage VSS is applied. For example, a first inverter of the cross-coupled inverter pair may include a pull-up transistor PU1 and a pull-down transistor PD1, and a second inverter of the cross-coupled inverter pair may include a pull-up transistor PU2 and a pull-down transistor PD2.

In this case, a first storage node M between the pull-up transistor PU1 and the pull-down transistor PD1 may be connected to the gate of the pull-up transistor PU2 and the gate of the pull-down transistor PD2, and a first complementary storage node M_B between the pull-up transistor PU2 and the pull-down transistor PD2 may be connected to the gate of the pull-up transistor PU1 and the gate of the pull-down transistor PD1. In this case, a voltage level of the first storage node M may correspond to a first value.

In addition, the first cell C1 may further include transfer transistors PG1 and PG2 configured to connect the first inverter and the second inverter to the bit line BL and the complementary bit line BLB, respectively, by an activated (e.g., having a high-level voltage) word line WL. In this case, the first storage node M may be connected to the bit line BL through the transfer transistor PG1, and the first complementary storage node M_B may be connected to the complementary bit line BLB through the transfer transistor PG2. For example, each of the pull-up transistors PU1 and PU2 may be a P-type transistor, and each of the pull-down transistors PD1 and PD2 and the transfer transistors PG1 and PG2 may be an N-type transistor.

The second cell C2 may include a cross-coupled inverter pair between a node to which a positive supply voltage, for example, the power supply voltage VDD is applied and a node to which a negative supply voltage, for example, the ground voltage VSS is applied. For example, a third inverter among the cross-coupled inverter pair may include a pull-up transistor PU3 and a pull-down transistor PD3, and a fourth inverter among the cross-coupled inverter pair may include a pull-up transistor PU4 and a pull-down transistor PD4.

In this case, a second storage node C between the pull-up transistor PU3 and the pull-down transistor PD3 may be connected to the gate of the pull-up transistor PU4 and the gate of the pull-down transistor PD4, and a second complementary storage node C_B between the pull-up transistor PU4 and the pull-down transistor PD4 may be connected to the gate of the pull-up transistor PU3 and the gate of the pull-down transistor PD3. In this case, a voltage level of the second storage node C may correspond to a second value.

In addition, the second cell C2 may further include transfer transistors PG3 and PG4 configured to connect the third inverter and the fourth inverter to the bit line BL and the complementary bit line BLB, respectively, by an activated (e.g., having a high-level voltage) word line WL. In this case, the second storage node C may be connected to the bit line BL through the transfer transistor PG3, and the first complementary storage node C_B may be connected to the complementary bit line BLB through the transfer transistor PG4. For example, each of the pull-up transistors PU3 and PU4 may be a P-type transistor, and each of the pull-down transistors PD3 and PD4 and the transfer transistors PG3 and PG4 may be an N-type transistor.

The comparison circuit CP may include data transistors DG1 and DG2 and search transistors SG1 and SG2. The data transistor DG1 may include a gate connected to the first storage node M and a source to which the ground voltage VSS is applied. The data transistor DG2 may include a gate connected to the second storage node C and a source to which the ground voltage VSS is applied. The search transistor SG1 may include a gate connected to the complementary search line SLB and a source connected to the data transistor DG1. The search transistor SG2 may include a gate connected to the search line SL and a source connected to the data transistor DG2. The search transistor SG1 may be configured to connect the data transistor DG1 to the match line ML by a complementary search line SLB, and the search transistor SG2 may be configured to connect the data transistor DG2 to the match line ML by a search line SL. The drains of the search transistors SG1 and SG2 may correspond to an output node of the memory cell MC.

The comparison circuit CP may compare search values input through the search line SL and the complementary search line SLB with first and second values stored in the first and second cells C1 and C2, and output the comparison result through the match line ML. In this case, search values input through the search line SL and the complementary search line SLB may be referred to as search data, and first and second values stored in the first and second cells C1 and C2 may be referred to as stored data. When the stored data matches the search data as a result of the comparison, a match may occur, and when the stored data and the search data do not match as a result of the comparison, a mismatch may occur. For example, during the comparison operation, the match line ML is precharged to a logic high level. The match line ML may be discharged to the logic low level when the comparison result is a match, and the match line ML may maintain the logic high level when the comparison result is a mismatch.

For example, when the memory cell MC stores “0”, that is, when the first value is 1 and the second value is 0, and when 0 is input to the search line SL and 1 is input to the complementary search line SLB, the data transistor DG1 and the search transistor SG1 may be turned on. In this case, since a match in which the stored data and the search data coincide occurs, the match line ML may be discharged. Meanwhile, for example, when the memory cell MC stores “0”, that is, when the first value is 1 and the second value is 0, and when 1 is input to the search line SL and 0 is input to the complementary search line SLB, the data transistor DG2 and the search transistor SG1 may be turned off. In this case, the match line ML may maintain the logic high level. For example, when the memory cell MC stores “x”, that is, when the first value is 1 and the second value is 1, the data transistors DG1 and DG2 may be turned on. Therefore, regardless of the search values input to the search line SL and the complementary search line SLB, the match line ML may be discharged.

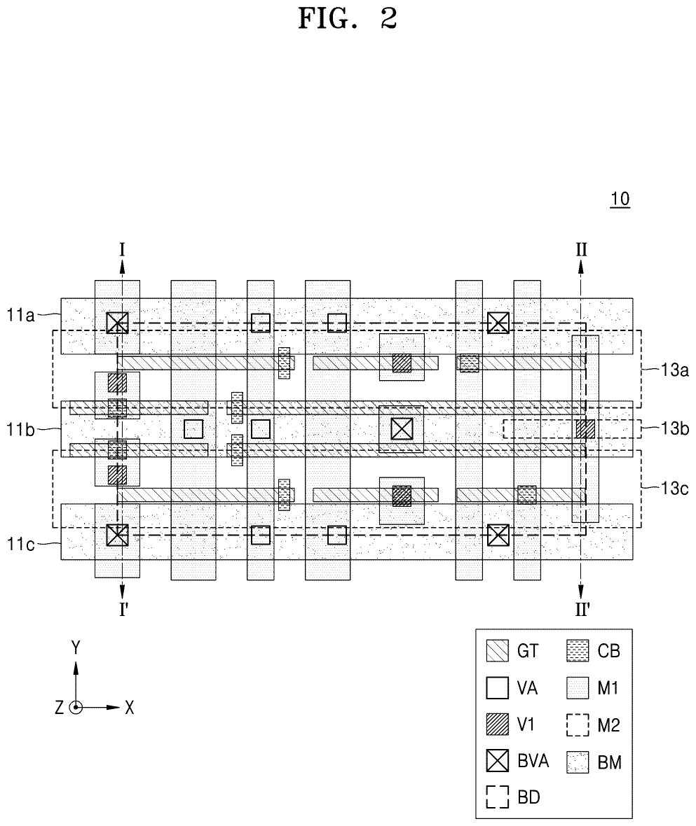

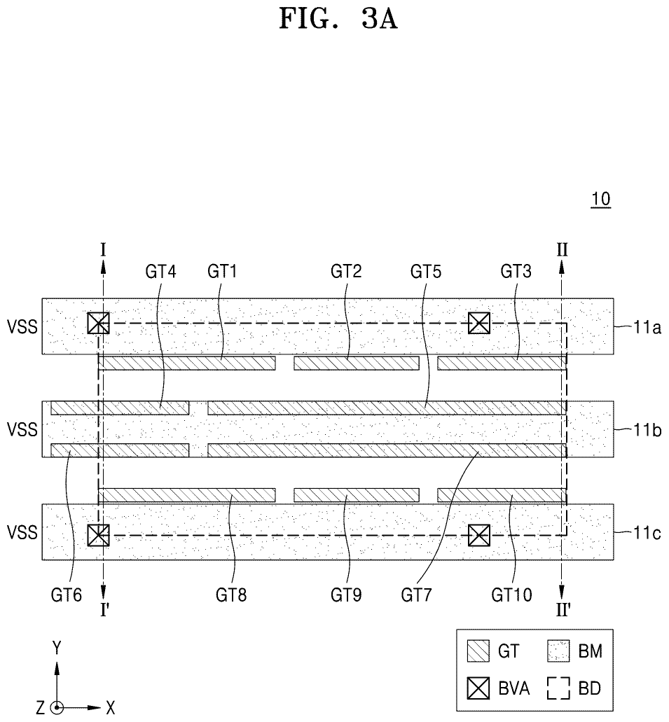

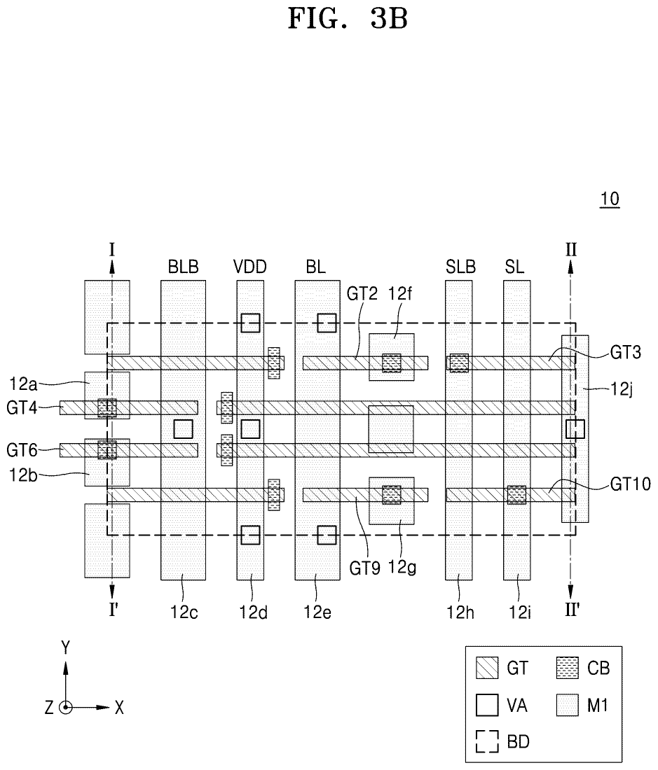

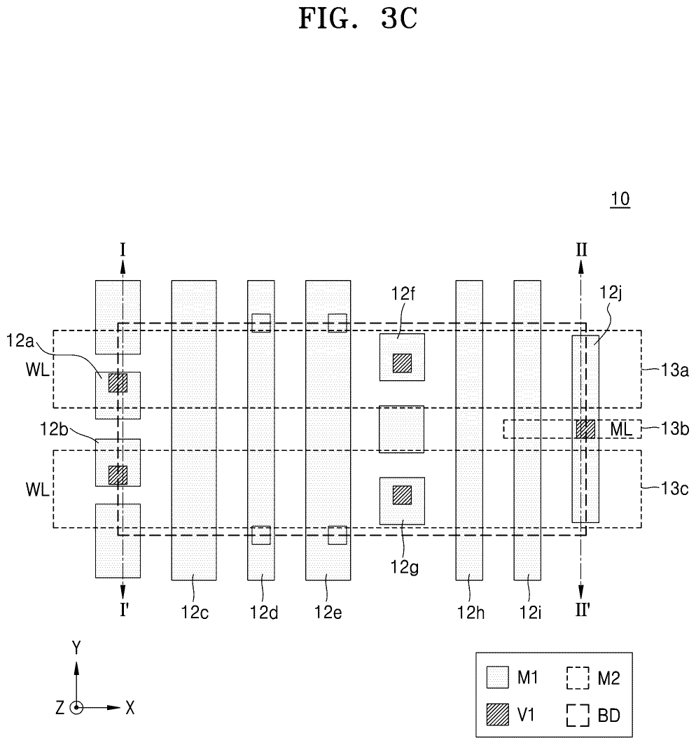

FIG. 2 is a layout diagram illustrating an example of an integrated circuit 10 including the memory cell of FIG. 1. FIG. 3A is a plan view illustrating an example of a backside wiring layer BM of the integrated circuit 10 of FIG. 2. FIG. 3B is a plan view illustrating an example of a first frontside wiring layer M1 of the integrated circuit 10 of FIG. 2. FIG. 3C is a plan view illustrating an example of a second frontside wiring layer M2 of the integrated circuit 10 of FIG. 2.

Referring to FIGS. 1 to 3C together, the integrated circuit 10 may include gate lines GT, gate contacts CB, first vias VA, second vias V1, a first frontside wiring layer M1, a second frontside wiring layer M2, a backside wiring layer BM, and backside vias BVA. In some implementations, the first and second frontside wiring layers M1 and M2 may be collectively referred to as frontside wiring layers. For example, the gate lines GT, the gate contacts CB, and the backside vias BVA may constitute a memory cell MC, e.g., a TCAM cell, and the memory cell MC may be implemented as a standard cell defined by a cell boundary BD.

The integrated circuit 10 may include the first and second frontside wiring layers M1 and M2 and the backside wiring layer BM, and may implement a power distribution network (PDN) using the first and second frontside wiring layers M1 and M2 and the backside wiring layer BM. In this case, the first and second frontside wiring layers M1 and M2 may be arranged above the standard cell, i.e., the memory cell MC in a vertical direction Z, and the backside wiring layer BM may be arranged below the standard cell, i.e., the memory cell MC in the vertical direction Z.

Thus, some of the signals and/or power applied to the integrated circuit 10 may be transferred through the first and second frontside wiring layers M1 and M2, and the rest may be transferred through the backside wiring layer BM. Therefore, routing complexity may be greatly reduced compared to a structure in which wirings are placed only on the front side of the substrate, and the length of each wiring or each via may be reduced, thereby improving the performance of the integrated circuit 10.

The integrated circuit 10 may be implemented as a semiconductor device, and a substrate on which the semiconductor device is formed may have a first surface and a second surface. The first surface may be, for example, a surface on which circuit elements such as transistors are arranged, and in the present specification, the first surface may be referred to as a “front side.” The second surface may be a surface facing the first surface, and in the present specification, the second surface may be referred to as a “back side”.

The gate lines GT may include a plurality of gate lines GT1 to GT10 extending in the first direction X. For example, the gate lines GT1 to GT3 may be arranged in a line in the first direction X, the gate lines GT4 and GT5 may be arranged in a line in the first direction X, the gate lines GT6 and GT7 may be arranged in a line in the first direction X, and the gate lines GT8 to GT10 may be arranged in a line in the first direction X. The gate contacts CB may be arranged on the gate lines GT1 to GT10, respectively.

In some implementations, the first and second frontside wiring layers M1 and M2 may be used as a signal wiring for transferring signals to the integrated circuit 10 and a power wiring for transferring power to the integrated circuit 10, and the backside wiring layer BM may be used as a power wiring for transferring power to the integrated circuit 10. For example, the first and second frontside wiring layers M1 and M2 may transfer a search line SL signal, a complementary search line SLB signal, and a word line WL signal to the memory cell MC, may transmit and receive a bit line BL signal and a complementary bit line BLB signal to and from the memory cell MC, and may receive a match line ML signal from the memory cell MC. In addition, the first and second frontside wiring layers M1 and M2 may provide the memory cell with power, such as a positive supply voltage, for example, a power supply voltage VDD. For example, the backside wiring layer BM may provide the memory cell MC with power such as a negative supply voltage, for example, a ground voltage VSS.

The backside wiring layer BM may include backside wiring lines 11a, 11b, and 11c each extending in the first direction X and spaced apart from each other in the second direction Y. For example, the backside wiring lines 11a, 11b, and 11c may be used as “backside power rails” that provide a supply voltage to the memory cell. For example, the backside wiring lines 11a, 11b, and 11c may be backside power rails that provide a negative supply voltage, e.g., a ground voltage VSS to the memory cell.

The backside vias BVA may be arranged on the backside wiring lines 11a, 11b, and 11c, respectively. Each of the backside wiring lines 11a, 11b, and 11c may be connected to the source/drain region of the transistor through a corresponding backside via BVA. For example, through the backside wiring lines 11a, 11b, and 11c, the ground voltage VSS may be provided to a source of each N-type transistor (e.g., each of PD1 to PD4, PG1 to PG4, SG1 and SG2, and DG1 and DG2).

In this way, backside vias BVA may connect layers and elements on the back side to elements in the substrate, for example, diffusion regions. Specifically, the backside vias BVA may be connected to source/drain regions of an active region, respectively. Here, the backside vias BVA may be “backside source/drain contacts”. As such, the structure of connecting the contact to the lower part of the epitaxial area, such as the source/drain area, may be referred to as a Direct Backside Contact (DBC). In some implementations, the DBC may include a backside contact and/or a backside via.

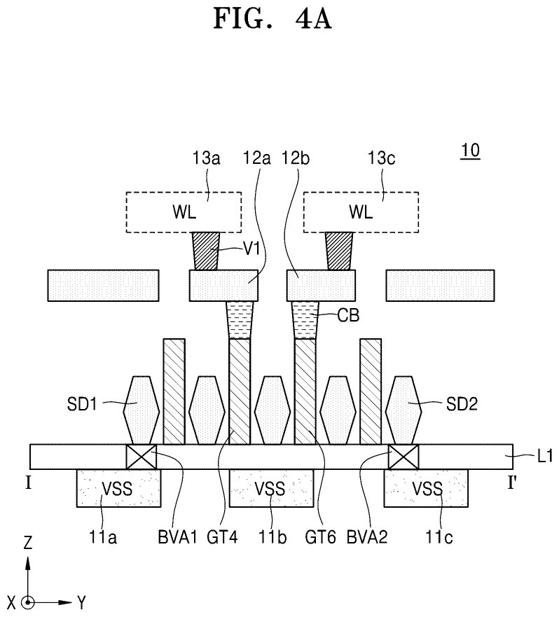

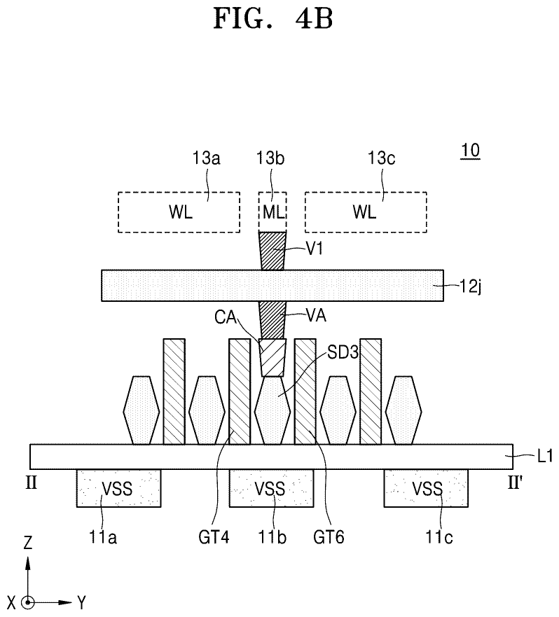

The first frontside wiring layer M1 may include a plurality of frontside wiring patterns each extending in the second direction Y. The frontside wiring patterns 12a, 12b, 12f, 12g, 12h, and 12i may be connected to the gate lines GT4, GT6, GT2, GT9, GT3, and GT10 through the gate contacts CB, respectively, and the frontside wiring patterns 12c, 12d, 12e, and 12j may be connected to the source/drain regions through first vias VA and source/drain contacts (e.g., CA of FIG. 4B).

The frontside wiring pattern 12c may correspond to the complementary bit line BLB, and may be connected to, for example, source/drain regions of the transfer transistors PG2 and PG4. The frontside wiring pattern 12d may correspond to the frontside power rail, and may transfer a power supply voltage VDD, for example, to sources of the pull-up transistors PU1 to PU4. For example, the frontside wiring pattern 12e may correspond to the bit line BL, and may be connected, for example, to source/drain regions of the transmission transistors PG1 and PG3.

The frontside wiring pattern 12h may correspond to the complementary search line SLB and may transfer a complementary search line (SLB) signal to the gate line GT3. For example, the gate line GT3 may correspond to the gate of the search transistor SG1. The frontside wiring pattern 12i may correspond to the search line SL, and may transmit a search line SL signal to the gate line GT10. For example, the gate line GT10 may correspond to the gate of the search transistor SG2.

The second frontside wiring layer M2 may include first to third frontside wiring lines 13a, 13b, and 13c extending in the first direction X, respectively. For example, the first and third frontside wiring lines 13a and 13c may correspond to the word line WL, and the second frontside wiring line 13b may correspond to the match line ML. The first frontside wiring line 13a may be connected to the frontside wiring patterns 12a and 12f through second vias V1, and the frontside wiring patterns 12a and 12f may transfer a word line WL signal to the gate lines GT4 and GT2 through the gate contacts CB, respectively. The third frontside wiring line 13c may be connected to the frontside wiring patterns 12b and 12g through the second vias V1, and the frontside wiring patterns 12b and 12g may transfer a word line WL signal to the gate lines GT6 and GT9 through the gate contacts CB, respectively. The second frontside wiring line 13b may be connected to the frontside wiring pattern 12j through the second via V1, and the frontside wiring pattern 12j may be connected to the source/drain region through the first via VA and the source/drain contact CA.

In this implementation, the ground voltage VSS may be supplied to the memory cell MC using the backside power rails included in the backside wiring layer BM, for example, the backside wiring lines 11a, 11b, and 11c. In this case, since the wiring width of the backside power rail may be arranged greater than the wiring width of the frontside power rail, the wiring width of each of the backside wiring lines 11a, 11b, and 11c may be increased, thereby smoothly supplying the ground voltage VSS to the memory cell MC.

In addition, the wiring width of the frontside wiring line included in the frontside wiring layer may be increased by arranging, on the backside wiring layer BM, the power rails that have been conventionally arranged on the frontside wiring layer. For example, the wiring width of each of the word lines included in the second frontside wiring layer M2, for example, the first and third frontside wiring lines 13a and 13c, may be increased, thereby further improving the performance of the integrated circuit 10 by reducing the word line resistance.

FIG. 4A is an example cross-sectional view taken along line I-I′ of FIG. 2, and FIG. 4B is an example cross-sectional view taken along line II-II′ of FIG. 2.

Referring to FIGS. 4A and 4B together, a first layer L1 may include a substrate or a semiconductor substrate. For example, the semiconductor substrate may include any one of silicon, silicon-on-insulator, silicon-on-sapphire, germanium, silicon-germanium, and gallium-arsenide. For example, the upper region of the first layer L1 may correspond to an active region. An interlayer insulating layer may be arranged above the first layer L1.

In some implementations, the first layer L1 may correspond to a bulkless substrate. During the manufacturing process of the integrated circuit 10, a device wafer may be formed by forming gate lines, source/drain regions, contacts, vias and/or wiring layers on the entire surface of the substrate. Subsequently, at least a part of the substrate may be removed by temporarily bonding the device wafer to a carrier wafer and performing a back-grinding process on the device wafer. In this way, a wafer that has been back-grinded so that the height of the substrate is below a reference height can be referred to as a bulkless wafer or a bulkless substrate.

Gate lines GT and source/drain regions SD may be arranged on the first layer L1. The gate lines GT may be defined as a conductive segment including a conductive material such as polysilicon and one or more metals. The source/drain regions SD may include an epitaxial region of a semiconductor material such as silicon, boron, phosphorus, germanium, carbon, SiGe, and/or SiC. The gate lines GT and the source/drain regions SD may constitute transistors.

The backside wiring lines 11a, 11b, and 11c may be arranged on the backside of the first layer L1. The backside wiring lines 11a, 11b, and 11c may extend in the first direction X, and may be spaced apart from each other in the second direction Y. For example, the backside wiring lines 11a, 11b, and 11c may receive the ground voltage VSS. The backside vias BVA1 and BVA2 may be arranged on the backside wiring lines 11a and 11c, respectively, and may extend in the vertical direction Z through the first layer L1. The backside via BVA1 may electrically connect the backside wiring line 11a to the source/drain region SD1, and the backside via BVA2 may electrically connect the backside wiring line 11c to the source/drain region SD2.

The gate line GT4 may be connected to the frontside wiring pattern 12a through the gate contact CB, and the frontside wiring pattern 12a may be connected to the first frontside wiring line 13a through the second via V1. The gate line GT6 may be connected to the frontside wiring pattern 12b through the gate contact CB, and the frontside wiring pattern 12b may be connected to the third frontside wiring line 13c through the second via V1. The first and third frontside wiring lines 13a and 13c may receive the word line WL signal, and thus the gate lines GT4 and GT6 may receive the word line WL signal.

The source/drain region SD3 may be connected to the frontside wiring pattern 12j through the source/drain contact CA and the first via VA, and the frontside wiring pattern 12j may be connected to the second frontside wiring line 13b through the second via V1. For example, the source/drain region SD3 may correspond to drains of the search transistors SG1 and SG2, and may be electrically connected to the second frontside wiring line 13b corresponding to the match line ML.

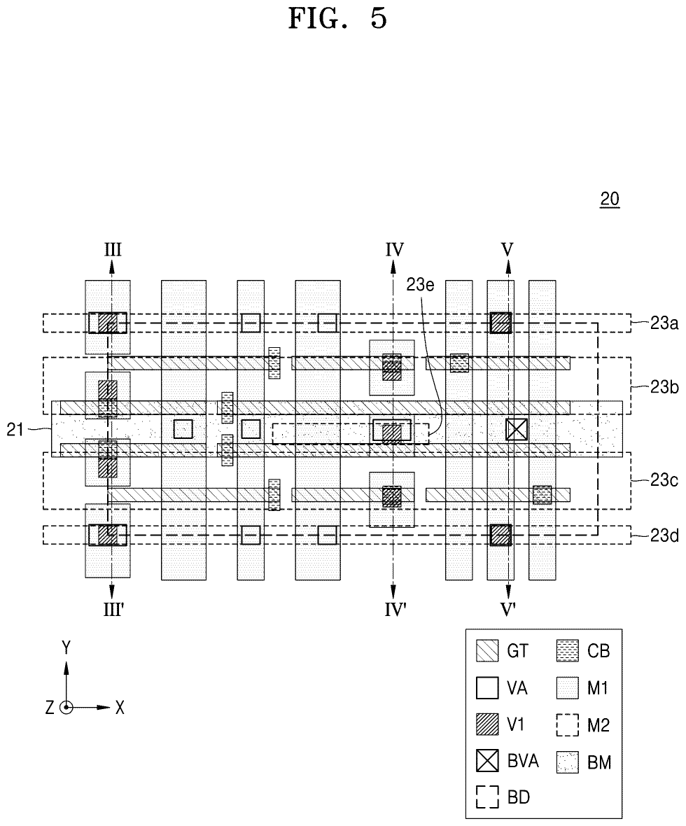

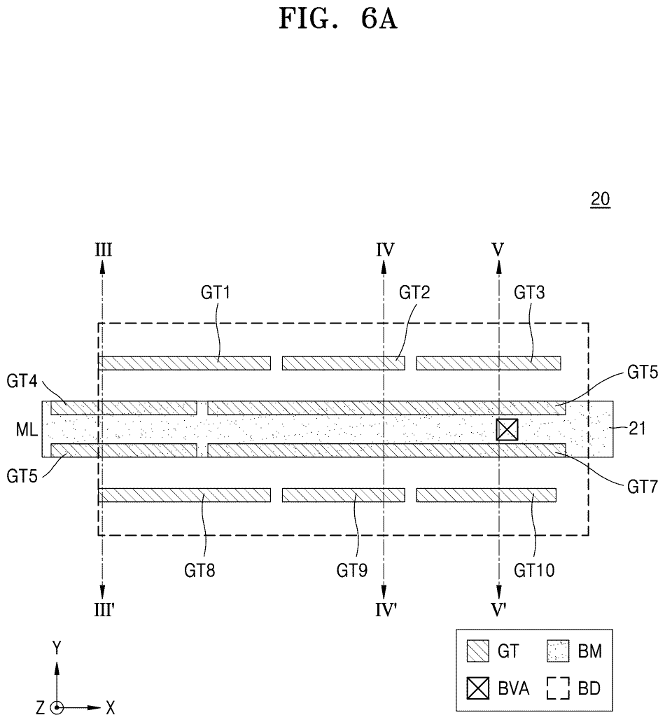

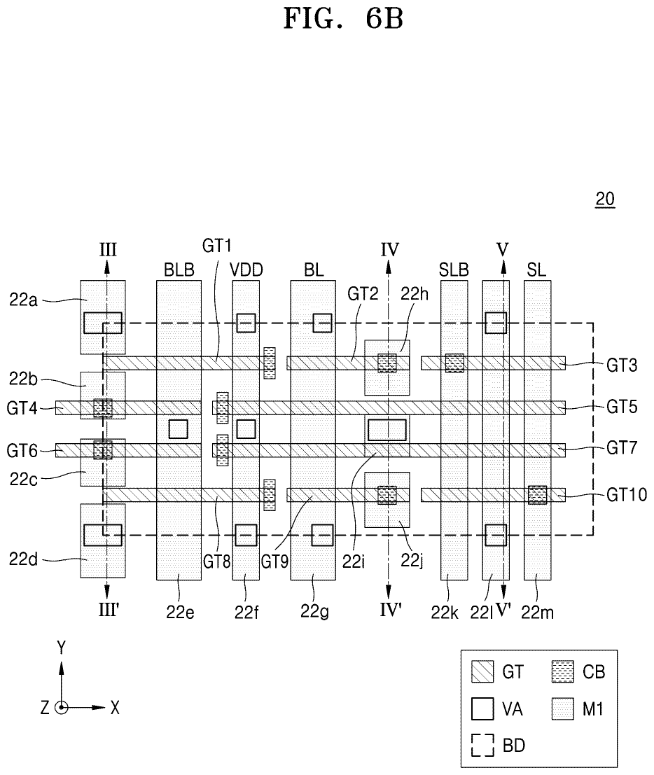

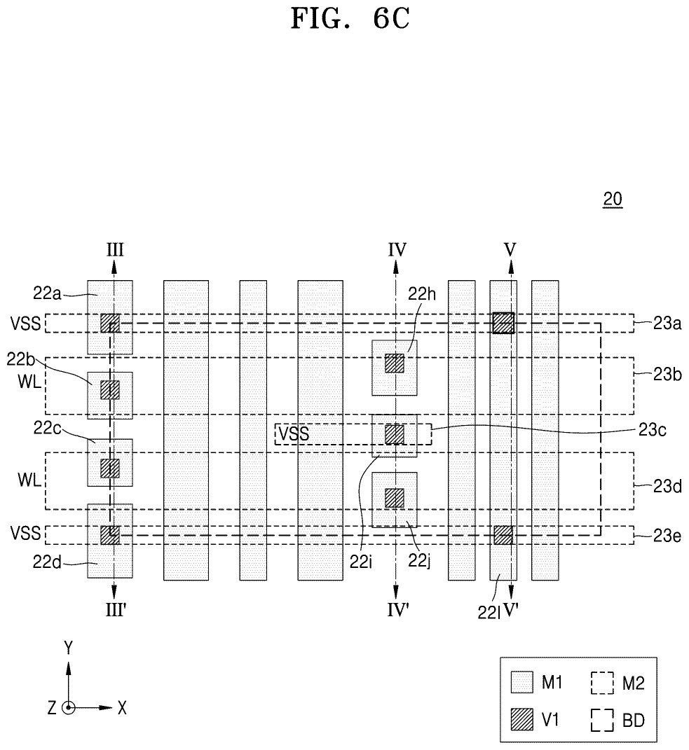

FIG. 5 is a layout diagram illustrating an example of an integrated circuit 20 including the memory cell of FIG. 1. FIG. 6A is a plan view illustrating an example of a backside wiring layer BM of the integrated circuit 20 of FIG. 5. FIG. 6B is a plan view illustrating an example of a first frontside wiring layer M1 of the integrated circuit 20 of FIG. 5. FIG. 6C is a plan view illustrating an example of a second frontside wiring layer M2 of the integrated circuit 20 of FIG. 5.

Referring to FIGS. 1 and 5 to 6C together, the integrated circuit 20 may include gate lines GT, gate contacts CB, first vias VA, second vias V1, a first frontside wiring layer M1, a second frontside wiring layer M2, a backside wiring layer BM, and a backside via BVA. For example, the gate lines GT, the gate contacts CB, and the backside via BVA may constitute a memory cell MC, e.g., a TCAM cell, and the memory cell MC may be implemented as a standard cell defined by a cell boundary BD. The integrated circuit 20 corresponds to a modified example of the integrated circuit 10 in FIG. 2, and the details described with reference to FIGS. 2 to 4B may be applied to this implementation.

The gate lines GT may include a plurality of gate lines GT1 to GT10 extending in the first direction X. The gate contacts CB may be arranged on the gate lines GT1 to GT10, respectively, and may be electrically connected to the gate lines GT1 to GT10, respectively.

In some implementations, the first and second frontside wiring layers M1 and M2 may be used as a signal wiring for transferring signals to the integrated circuit 20 and a power wiring for transferring power to the integrated circuit 20, and the backside wiring layer BM may be used as a signal wiring for transferring signals to the integrated circuit 20. For example, the first and second frontside wiring layers M1 and M2 may transfer a search line SL signal, a complementary search line SLB signal, and a word line WL signal to the memory cell MC, and may transmit and receive a bit line BL signal and a complementary bit line BLB to and from the memory cell MC. In addition, through the first and second frontside wiring layers M1 and M2, power such as a positive supply voltage, for example, a power supply voltage VDD and a negative supply voltage, for example, a ground voltage VSS, may be provided to the memory cell MC. For example, the backside wiring layer BM may receive a match line ML signal from the memory cell MC.

The backside wiring layer BM may include a backside wiring line 21 extending in the first direction X. For example, the backside wiring line 21 may correspond to the match line ML. The backside wiring line 21 may be connected to the source/drain region of the transistor through the backside via BVA. Here, the backside via BVA may be a “backside source/drain contact”. For example, the backside wiring line 21 may be connected to the drains of the search transistors SG1 and SG2 of FIG. 1. In this case, the backside via BVA may correspond to the DBC. In some implementations, a backside contact may be arranged between the backside via BVA and the source/drain region or between the backside wiring line 21 and the backside via BVA.

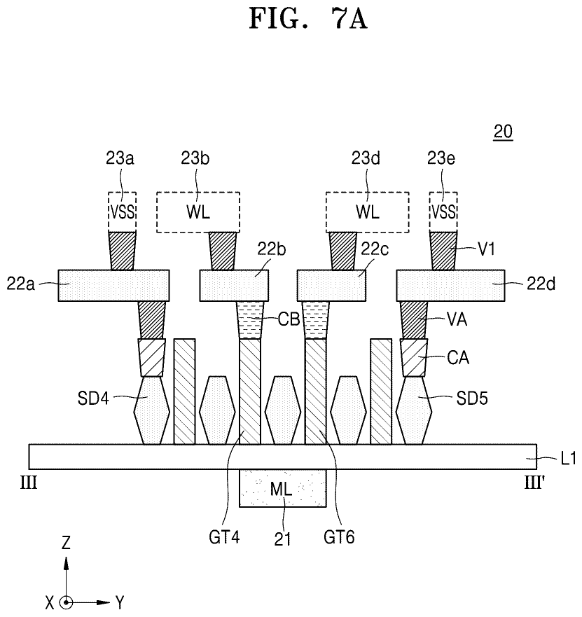

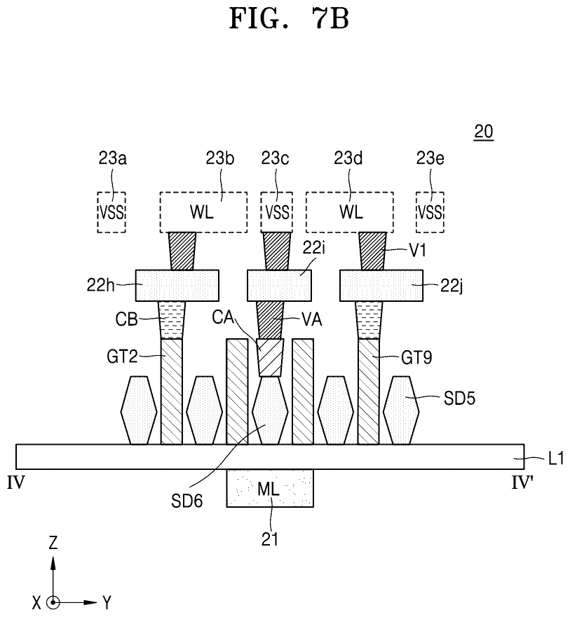

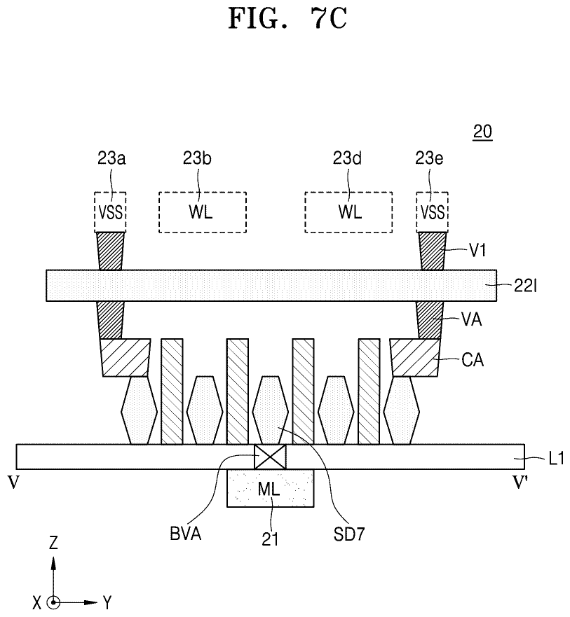

The first frontside wiring layer M1 may include a plurality of frontside wiring patterns 22a to 22m each extending in the second direction Y. The frontside wiring patterns 22b, 22c, 22h, 22j, 22k, and 22m may be connected to the gate lines GT4, GT6, GT2, GT9, GT3, and GT10 through the gate contacts CB, respectively. The frontside wiring patterns 22a, 22d, 22e, 22f, 22g, 22i, and 22l may be connected to the source/drain regions through first vias VA and source/drain contacts (e.g., CA of FIGS. 7A to 7C).

The frontside wiring pattern 22e may correspond to the complementary bit line BLB, and may be connected to, for example, source/drain regions of the transfer transistors PG2 and PG4. The frontside wiring pattern 22f may correspond to the frontside power rail, and may transfer a power supply voltage VDD, for example, to sources of the pull-up transistors PU1 to PU4. For example, the frontside wiring pattern 22g may correspond to the bit line BL, and may be connected, for example, to source/drain regions of the transmission transistors PG1 and PG3.

The frontside wiring pattern 22k may correspond to the complementary search line SLB and may transfer a complementary search line (SLB) signal to the gate line GT3. For example, the gate line GT3 may correspond to the gate of the search transistor SG1. The frontside wiring pattern 22m may correspond to the search line SL, and may transmit a search line SL signal to the gate line GT10. For example, the gate line GT10 may correspond to the gate of the search transistor SG2.

The second frontside wiring layer M2 may include first to fifth frontside wiring lines 23a to 23e each extending in the first direction X. For example, the first, third, and fifth frontside wiring lines 23a, 23c, and 23e may correspond to power rails that provide the ground voltage VSS. The first frontside wiring line 23a may be connected to the frontside wiring patterns 22a and 22l through the second vias V1, and the frontside wiring patterns 22a and 22l may transfer the ground voltage VSS to the source/drain regions through the first vias VA and the source/drain contacts CA. The third frontside wiring line 23c may be connected to the frontside wiring pattern 22i through the second via V1, and the frontside wiring pattern 22i may transfer the ground voltage VSS to the source/drain region through the first via VA and the source/drain contact CA. The fifth frontside wiring line 23e may be connected to the frontside wiring patterns 22d and 22l through the second vias V1, and the frontside wiring patterns 22d and 22h may transfer the ground voltage VSS to the source/drain regions through the first vias VA and the source/drain contacts CA.

For example, the second and fourth frontside wiring lines 23b and 23d may correspond to the word line WL. The second frontside wiring line 23b may be connected to the frontside wiring patterns 22b and 22h through the second vias V1, and the frontside wiring patterns 22b and 22h may transfer a word line WL signal to the gate lines GT4 and GT2 through the gate contacts CB, respectively. The fourth frontside wiring line 23d may be connected to the frontside wiring patterns 22c and 22j through the second vias V1, and the frontside wiring patterns 22c and 22j may transfer a word line WL signal to the gate lines GT6 and GT9 through the gate contacts CB, respectively.

According to the present implementation, the match line ML may be implemented using the backside signal line included in the backside wiring layer BM, for example, the backside wiring line 21. In this case, since the wiring width of the backside signal line may be placed greater than the wiring width of the frontside signal line, the wiring width of the backside wiring line 21 may be increased, thereby smoothly outputting the match line ML signal from the memory cell MC to improve the performance of the integrated circuit 20.

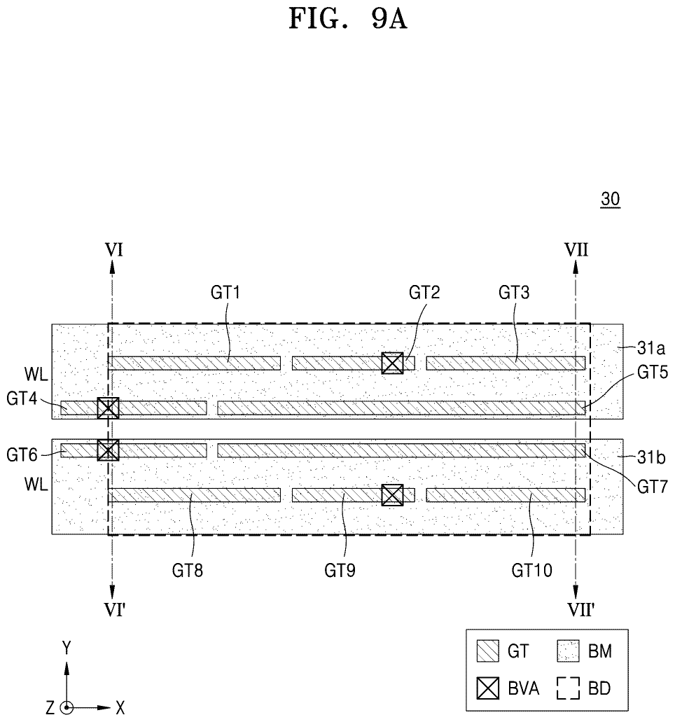

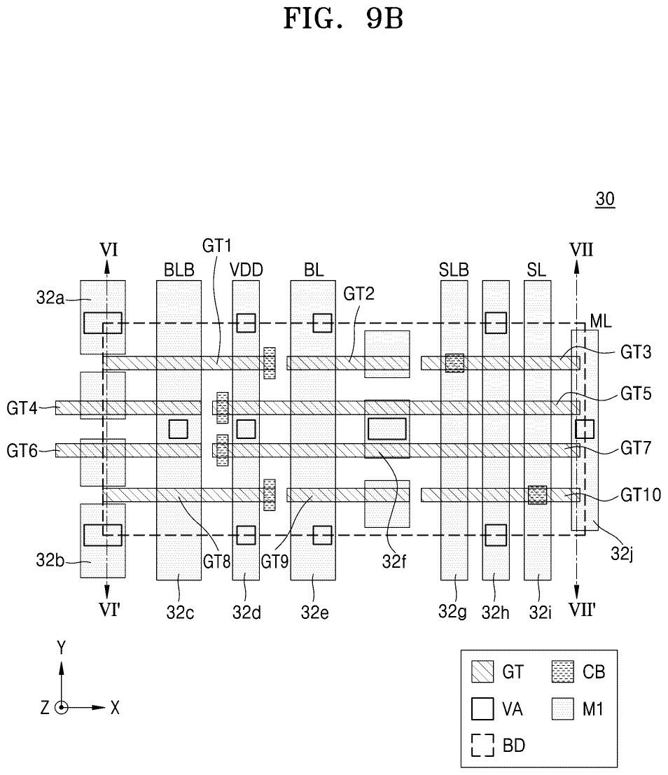

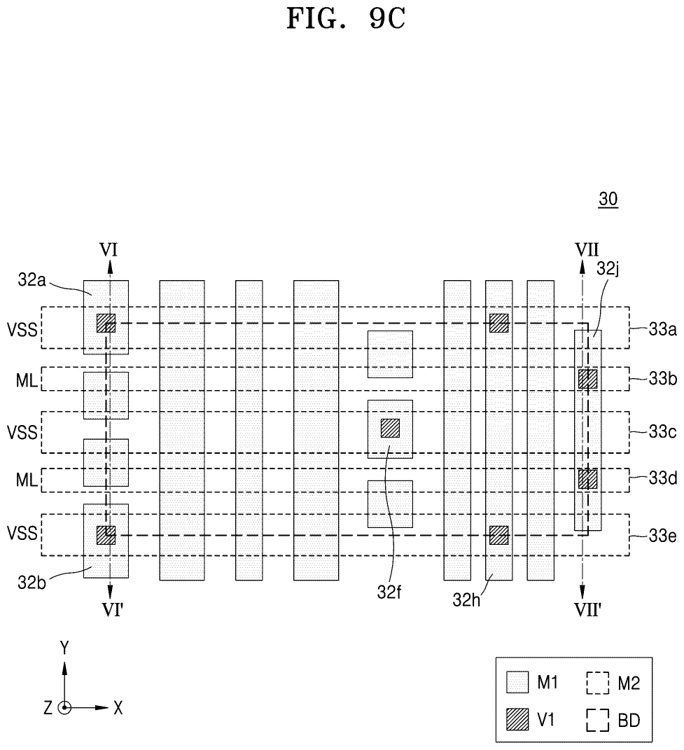

In addition, as the match line ML previously placed on the frontside wiring layer is deleted, the width of the memory cell MC in the first direction X may be reduced, thereby reducing the area of the integrated circuit 20. For example, the first frontside wiring layer M1 of the integrated circuit 20 may not include a signal line corresponding to the frontside wiring pattern 32j of FIG. 9B. Therefore, the width of the memory cell MC1 in the first direction X may be reduced according to the size of the active region in which the comparison circuit CP is implemented, for example, the nanosheet.

FIG. 7A is an example cross-sectional view taken along line III-III′ of FIG. 5. FIG. 7B is an example cross-sectional view taken along line IV-IV′ of FIG. 5. FIG. 7C is an example cross-sectional view taken along line V-V′ of FIG. 5. The above description with reference to FIGS. 4A and 4B may be applied to the present implementation.

Referring to FIG. 7A, the gate line GT4 may be connected to the frontside wiring pattern 22b through a gate contact CB, and the frontside wiring pattern 22b may be connected to the second frontside wiring line 23b through a second via V1. The gate line GT6 may be connected to the frontside wiring pattern 22c through the gate contact CB, and the frontside wiring pattern 22c may be connected to the fourth frontside wiring line 23d through the second via V1. The second and fourth frontside wiring lines 23b and 23d may receive the word line WL signal, and thus the gate lines GT4 and GT6 may receive the word line WL signal.

The source/drain region SD4 may be connected to the frontside wiring pattern 22a through the source/drain contact CA and the first via VA, and the frontside wiring pattern 22a may be connected to the first frontside wiring line 23a through the second via V1. The source/drain region SD5 may be connected to the frontside wiring pattern 22d through the source/drain contact CA and the first via VA, and the frontside wiring pattern 22d may be connected to the fifth frontside wiring line 23e through the second via V1. Accordingly, the source/drain regions SD4 and SG5 may receive the ground voltage VSS from the first and fifth frontside wiring lines 23a and 23e, respectively.

Referring to FIG. 7B, the gate line GT2 may be connected to the frontside wiring pattern 22h through the gate contact CB, and the frontside wiring pattern 22h may be connected to the second frontside wiring line 23b through the second via V1. The gate line GT9 may be connected to the frontside wiring pattern 22j through the gate contact CB, and the frontside wiring pattern 22j may be connected to the fourth frontside wiring line 23d through the second via V1. The second and fourth frontside wiring lines 23b and 23d may receive the word line WL signal, and thus the gate lines GT2 and GT9 may receive the word line WL signal.

The source/drain region SD6 may be connected to the frontside wiring pattern 22i through the source/drain contact CA and the first via VA, and the frontside wiring pattern 22i may be connected to the third frontside wiring line 23c through the second via V1. Accordingly, the source/drain region SD6 may receive the ground voltage VSS from the third frontside wiring line 23c.

Referring to FIG. 7C, the backside wiring line 21 may be arranged on the back side of the first layer L1 and may extend in the first direction X. For example, the backside wiring line 21 may correspond to the match line ML. The backside via BVA may be arranged on the backside wiring line 21 and extend in the vertical direction Z by penetrating the first layer L1. The backside wiring line 21 may be electrically connected to the source/drain region SD7 through a backside via BVA. As a result, the output of the memory cell MC representing a match or mismatch may be transmitted from the source/drain region SD7 to the backside wiring line 21. Here, the backside via BVA may correspond to the DBC. In some implementations, a backside contact may be further arranged between the backside via BVA and the source/drain region SD7 or between the backside wiring line 21 and the backside via BVA.

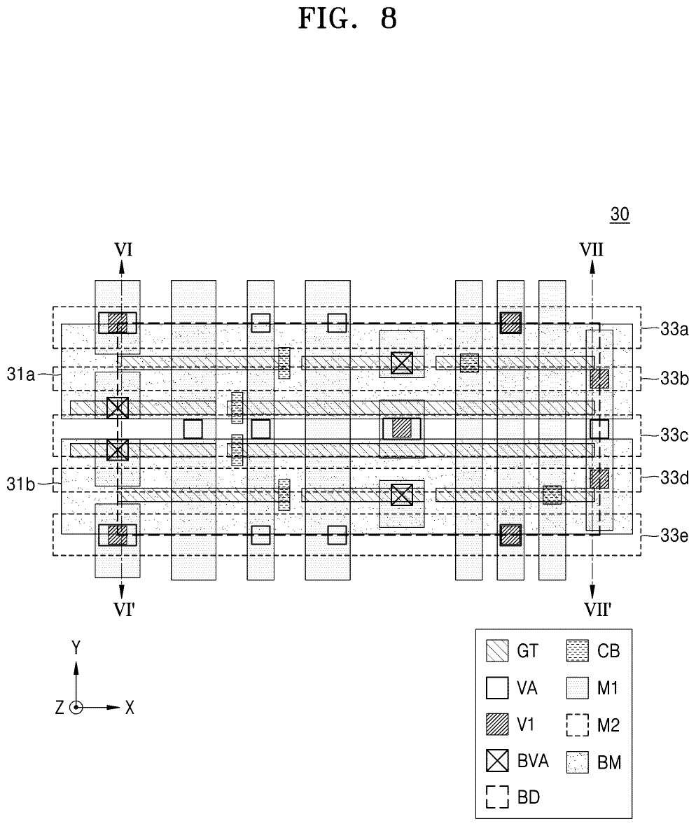

FIG. 8 is a layout diagram illustrating an example of an integrated circuit 30 including the memory cell of FIG. 1. FIG. 9A is a plan view illustrating an example of a backside wiring layer BM of the integrated circuit 30 of FIG. 8. FIG. 9B is a plan view illustrating an example of a first frontside wiring layer M1 of the integrated circuit 30 of FIG. 8. FIG. 9C is a plan view illustrating an example of a second frontside wiring layer M2 of the integrated circuit 30 of FIG. 8.

Referring to FIGS. 1 and 8 to 9C together, the integrated circuit 30 may include gate lines GT, gate contacts CB, first vias VA, second vias V1, a first frontside wiring layer M1, a second frontside wiring layer M2, a backside wiring layer BM, and backside vias BVA. For example, the gate lines GT, the gate contacts CB, and the backside vias BVA may constitute a memory cell MC of FIG. 1, e.g., a TCAM cell, and the memory cell MC may be implemented as a standard cell defined by a cell boundary BD. The integrated circuit 20 corresponds to a modified example of the integrated circuit 10 in FIG. 2, and the details described with reference to FIGS. 2 to 4B may be applied to this implementation.

The gate lines GT may include a plurality of gate lines GT1 to GT10 extending in the first direction X. The backside vias BVA may be arranged below each of the gate lines GT2, GT4, GT6, and GT9, and may be electrically connected to each of the gate lines GT2, GT4, GT6, and GT9. The gate contacts CB may be arranged on the gate lines GT1, GT3, GT5, GT7, GT8, and GT10, respectively, and may be electrically connected to the gate lines GT1, GT3, GT5, GT7, GT8, and GT10.

In some implementations, the first and second frontside wiring layers M1 and M2 may be used as a signal wiring for transferring signals to the integrated circuit 30 and a power wiring for transferring power to the integrated circuit 30, and the backside wiring layer BM may be used as a signal wiring for transferring signals to the integrated circuit 30. For example, a bit line BL signal and a complementary bit line BLB signal may be transmitted and received to and from the memory cell MC through the first and second frontside wiring layers M1 and M2, a search line SL signal and a complementary search line SLB signal may be transferred to the memory cell MC therethrough, and a match line ML signal may be received from the memory cell MC therethrough. In addition, through the first and second frontside wiring layers M1 and M2, power such as a positive supply voltage, for example, a power supply voltage VDD and a negative supply voltage, for example, a ground voltage VSS, may be provided to the memory cell MC. For example, the backside wiring layer BM may transfer the word line WL signal to the memory cell MC.

The backside wiring layer BM may include backside wiring lines 31a and 31b extending in the first direction X. For example, the backside wiring lines 31a and 31b may correspond to the word line WL. The backside wiring line 31a may transfer the word line WL signal to the gate lines GT2 and GT4 through the backside vias BVA, and the backside wiring line 31b may transfer the word line WL signal to the gate lines GT6 and GT9 through the backside vias BVA. Here, the backside vias BVA may be “backside gate contacts”.

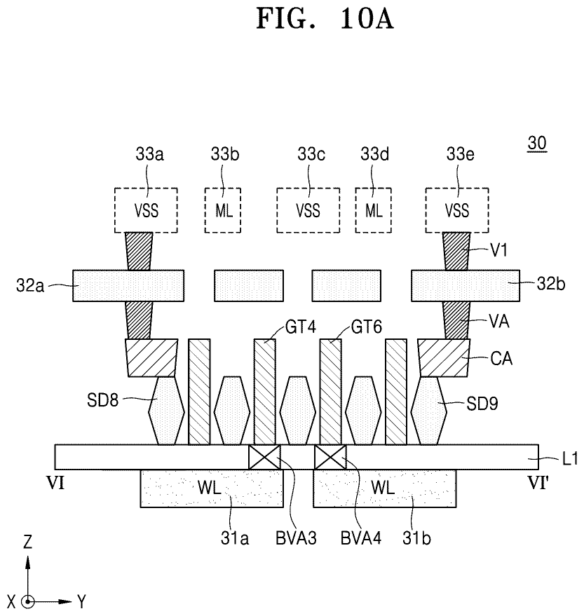

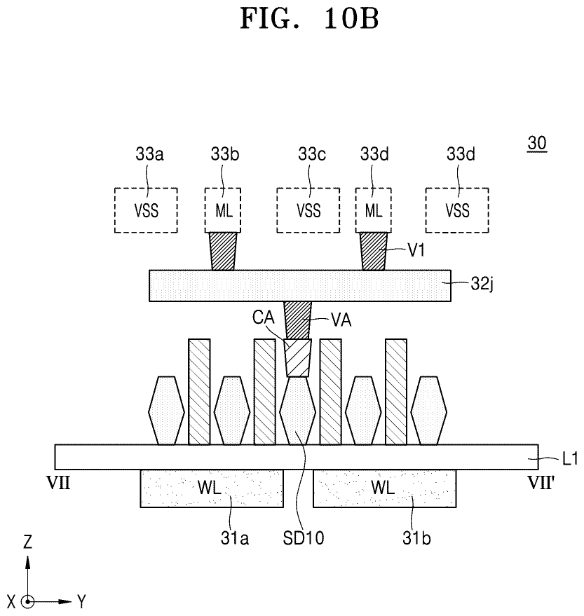

The first frontside wiring layer M1 may include a plurality of frontside wiring patterns 32a to 32j each extending in the second direction Y. The frontside wiring patterns 32a, 32b, 32c, 32d, 32e, 32f, 32h, and 32j may be connected to source/drain regions through first vias VA and source/drain contacts (e.g., CA of FIGS. 10A and 10B). The frontside wiring patterns 32g and 32i may be connected to the gate lines GT3 and GT10 through the gate contacts CB, respectively,

The frontside wiring pattern 32c may correspond to the complementary bit line BLB, and may be connected to, for example, source/drain regions of the transfer transistors PG2 and PG4. The frontside wiring pattern 32d may correspond to the frontside power rail, and may transfer a power voltage VDD, for example, to sources of the pull-up transistors PU1 to PU4. For example, the frontside wiring pattern 32e may correspond to the bit line BL, and may be connected, for example, to source/drain regions of the transmission transistors PG1 and PG3.

The frontside wiring pattern 32g may correspond to the complementary search line SLB and may transfer a complementary search line (SLB) signal to the gate line GT3. For example, the gate line GT3 may correspond to the gate of the search transistor SG1. The frontside wiring pattern 32i may correspond to the search line SL, and may transmit a search line SL signal to the gate line GT10. For example, the gate line GT10 may correspond to the gate of the search transistor SG2.

The second frontside wiring layer M2 may include first to fifth frontside wiring lines 33a to 33e each extending in the first direction X. For example, the first, third, and fifth frontside wiring lines 33a, 33c, and 33e may correspond to power rails that provide the ground voltage VSS. The first frontside wiring line 33a may be connected to the frontside wiring patterns 32a and 32h through the second vias V1, and the frontside wiring patterns 32a and 32h may transfer the ground voltage VSS to the source/drain regions through the first vias VA and the source/drain contacts CA. The third frontside wiring line 33c may be connected to the frontside wiring pattern 32f through the second via V1, and the frontside wiring pattern 32f may transfer the ground voltage VSS to the source/drain region through the first via VA and the source/drain contact CA. The fifth frontside wiring line 33e may be connected to the frontside wiring patterns 32b and 32h through the second vias V1, and the frontside wiring patterns 32b and 32h may transfer the ground voltage VSS to the source/drain regions through the first vias VA and the source/drain contacts CA.

For example, the second and fourth frontside wiring lines 33b and 33d may correspond to the match line ML. The second and fourth frontside wiring lines 33b and 33d may be connected to the frontside wiring pattern 32j through second vias V1, and the frontside wiring pattern 32j may be connected to the source/drain region through the first via VA and the source/drain contact CA.

According to the present implementation, a word line WL may be implemented by using backside signal lines, for example, backside wiring lines 31a and 31b included in a backside wiring layer BM. In this case, since the wiring width of the backside signal line may be arranged greater than the wiring width of the frontside signal line, the wiring width of each of the backside wiring lines 21a and 21b may be increased. As a result, it is possible to reduce word line resistance and smoothly supply word line WL signals to the memory cell MC to improve the performance of the integrated circuit 30.

In addition, the wiring width of the frontside wiring line included in the frontside wiring layer may be increased by arranging, on the backside wiring layer BM, the word lime that have been conventionally arranged on the frontside wiring layer. For example, it is possible to increase the wiring width of each of the power rails included in the second frontside wiring layer M2, for example, the first, third, and fifth frontside wiring lines 33a, 33c, and 33e, thereby smoothly supplying the ground voltage VSS to the memory cell MC. In addition, for example, it is possible to increase the wiring width of each of the match lines ML included in the second frontside wiring layer M2, for example, the second and fourth frontside wiring lines 33b and 33d, thereby smoothly outputting the match line ML signal from the memory cell MC to improve the performance of the integrated circuit 30.

FIG. 10A is an example cross-sectional view taken along line VI-VI′ of FIG. 8, and FIG. 10B is an example cross-sectional view taken along line VII-VII′ of FIG. 8. The above description with reference to FIGS. 4A and 4B may be applied to the present implementation.

Referring to FIG. 10A, the backside wiring lines 31a and 31b may be arranged on the back side of the first layer L1. The backside wiring lines 31a and 31b may extend in the first direction X, and may be spaced apart from each other in the second direction Y. For example, the backside wiring lines 31a and 31b may correspond to the word line WL. The backside vias BVA3 and BVA4 may be arranged on the backside wiring lines 31a and 31b, respectively, and may extend in the vertical direction Z through the first layer L1. The backside wiring line 31a may be electrically connected to the gate line GT4 through a backside via BVA3. The backside wiring line 31b may be electrically connected to the gate line GT6 through a backside via BVA4. Accordingly, the gate lines GT4 and GT6 may receive the word line WL signal.

The source/drain region SD8 may be connected to the frontside wiring pattern 32a through the source/drain contact CA and the first via VA, and the frontside wiring pattern 32a may be connected to the first frontside wiring line 33a through the second via V1. The source/drain region SD9 may be connected to the frontside wiring pattern 32b through the source/drain contact CA and the first via VA, and the frontside wiring pattern 32b may be connected to the fifth frontside wiring line 33e through the second via V1. Accordingly, the source/drain regions SD8 and SD9 may receive the ground voltage VSS.

Referring to FIG. 10B, the source/drain region SD10 may be connected to the frontside wiring pattern 32j through the source/drain contact CA and the first via VA, and the frontside wiring pattern 32j may be connected to the second and fourth frontside wiring lines 33b and 33d through the second via V1. Thus, the source/drain region SD10 may be electrically connected to the match line ML.

FIG. 11 is a block diagram illustrating an example of a memory device 40.

Referring to FIG. 11, the memory device 40 may include a cell array 41, a row decoder 42, a search driver 43, a read/write circuit 44, and a match circuit 45. Here, the row decoder 42, the search driver 43, the read/write circuit 44, and the match circuit 45 may be collectively referred to as peripheral circuits. In some implementations, the peripheral circuits may further include a control circuit, a command buffer, an address buffer, a voltage generator, and/or a data input/output circuit.

The cell array 41 may include a plurality of memory cells, and each memory cell may correspond to the memory cell MC of FIG. 1, for example, a TCAM cell. Accordingly, the cell array 41 may be implemented as the layout described above with reference to FIGS. 2 to 10B. The row decoder 42 may be connected to the cell array 41 through a plurality of word lines WL, and may activate a selected word line among the plurality of word lines WL in response to a command and an address. Accordingly, memory cells connected to an activated selection word line may be selected from among the memory cells included in the cell array 41.

The search driver 43 may be connected to the cell array 41 through a plurality of search lines SLs, and may provide a search word for searching for a memory address to the cell array 41. Accordingly, the search data or the search word may be input to the cell array 41 through a search line. The read/write circuit 44 may be connected to the cell array 41 through a plurality of bit lines BLs, and may latch write data and read data. During a write operation, the read/write circuit 44 may function as a write driver that provides write data to the cell array 41 through the plurality of bit lines BLs. During a read operation, the read/write circuit 44 may function as a sense amplifier for receiving read data from the cell array 41 through the plurality of bit lines BLs.

The match circuit 45 may be connected to the cell array 41 through the plurality of match lines MLs. The match circuit 45 may function as an encoder that outputs an address corresponding to the currently input search data in response to a logical state of the plurality of match lines MLs. For example, the match circuit 45 may output an address of a memory cell that stores data matching search data based on the voltage received through the match line ML.

In some implementations, a backside wiring layer including a backside power rail may be arranged under the cell array 41. For example, each memory cell MC may receive the ground voltage VSS from the backside power rail via the backside via or the DBC. In some implementations, a backside wiring layer including the match line ML may be arranged under the cell array 41. For example, the output node of each memory cell MC may be connected to the match line ML through the backside via or the DBC. In some implementations, a backside wiring layer including the word line WL may be arranged under the cell array 41. For example, each memory cell MC may be connected to the word line WL through the backside via.

In some implementations, a backside wiring layer including a backside power rail and a match line ML may be arranged under the cell array 41, and each memory cell MC may receive a supply voltage from the backside power rail and output a comparison result through the match line ML. In some implementations, a backside wiring layer including a backside power rail and a word line WL may be arranged under the cell array 41, and each memory cell MC may receive a supply voltage from the backside power rail and a word line signal through the word line WL. In some implementations, a backside wiring layer including a match line ML and a word line WL may be arranged under the cell array 41, and each memory cell MC may output a comparison result through the match line ML and receive a word line signal through the word line WL. In some implementations, a backside wiring layer including a backside power rail, a match line ML, and a word line WL may be arranged under the cell array 41, and each memory cell MC may receive a supply voltage from the backside power rail, output a comparison result through the match line ML, and receive a word line signal through the word line WL.

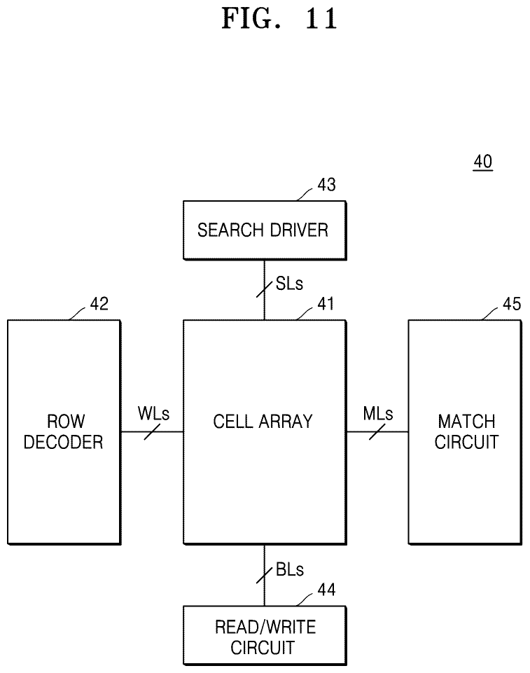

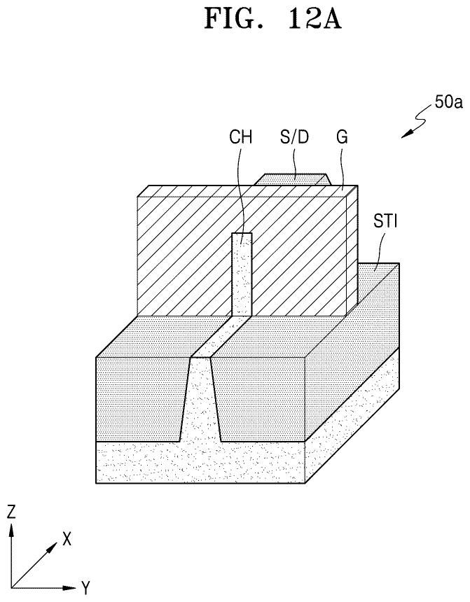

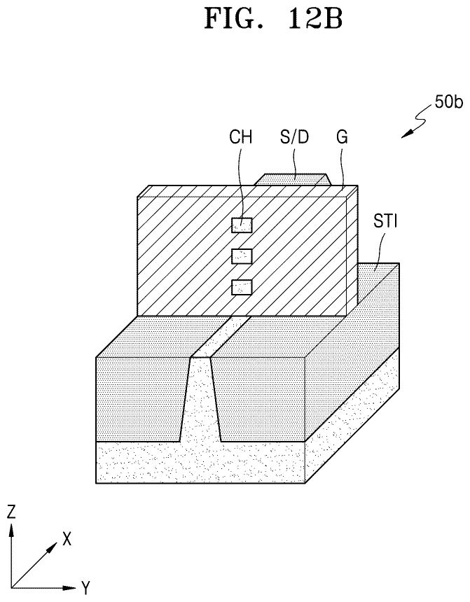

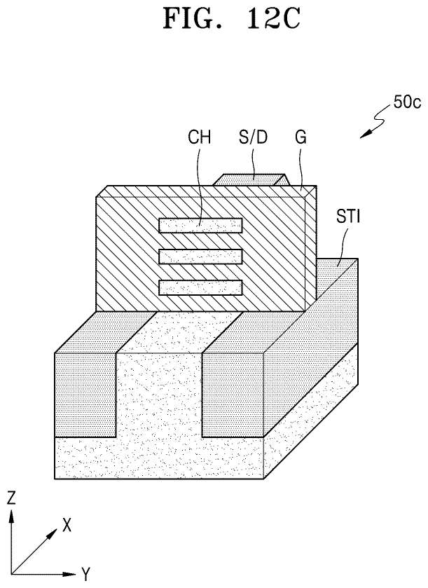

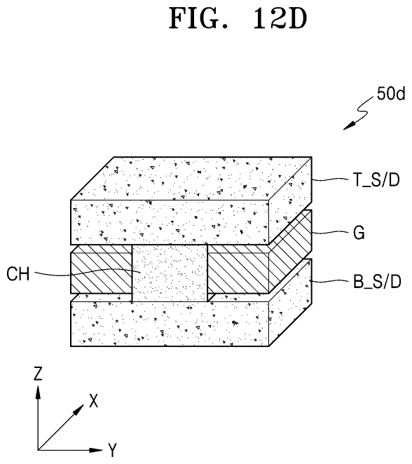

FIGS. 12A to 12D are diagrams illustrating an example of an element. For example, FIG. 12A illustrates FinFET 50a, FIG. 12B illustrates gate-all-around field effect transistor (GAAFET) 50b, FIG. 12C illustrates multi-bridge channel field effect transistor (MBCFET) 50c, and FIG. 12D illustrates virtual field effect transistor (VFET) 50d. For convenience of illustration, FIGS. 12A to 12C illustrate a state in which one of two source/drain regions is removed, and FIG. 12D illustrates a cross-section in which the VFET 50d is cut into a plane parallel to a plane formed in a second direction Y and a vertical direction Z and passing through the channel CH of the VFET 50d.

Referring to FIG. 12A, the FinFET 50a may be formed by a fin-shaped active pattern extending in the first direction X and a gate G extending in the second direction Y between shallow trench isolators (STIs). Source/drain S/D may be formed at both sides of the gate G, and accordingly, the source and drain may be spaced apart from each other in the first direction X. An insulating layer may be formed between the channel CH and the gate G. In some implementations, the FinFET 50a may be formed by a plurality of active patterns and a gate G spaced apart from each other in the second direction Y.

Referring to FIG. 12B, GAAFET 50b may be formed by active patterns spaced apart from each other in the vertical direction Z and extending in the first direction X, that is, nanowires, and a gate G extending in the second direction Y. Source/drain S/D may be formed at both sides of the gate G, and accordingly, the source and drain may be spaced apart from each other in the first direction X. An insulating layer may be formed between the channel CH and the gate G. It is noted that the number of nanowires included in the GAAFET 50b is not limited to that shown in FIG. 12B.

Referring to FIG. 12C, MBCFET 50c may be formed by active patterns spaced apart from each other in the vertical direction Z and extending in the first direction X, that is, nanosheets, and a gate G extending in the second direction Y. Source/drain S/D may be formed at both sides of the gate G, and accordingly, the source and drain may be spaced apart from each other in the first direction X. An insulating layer may be formed between the channel CH and the gate G. It is noted that the number of nanosheets included in the MBCFET 50c is not limited to that shown in FIG. 12C.

Referring to FIG. 12D, VFET 50d may include a top source/drain T_S/D and a bottom source/drain B_S/D spaced apart from each other in the vertical direction Z with a channel CH therebetween. The VFET 50d may include a gate G surrounding the circumference of the channel CH between the top source/drain T_S/D and the bottom source/drain B_S/D. An insulating layer may be formed between the channel CH and the gate G.

However, the transistor is not limited to the structure described above. For example, an integrated circuit may include a ForkFET in which N-type transistors and P-type transistors are closer to each other by separating nanosheets for P-type transistors from nanosheets for N-type transistors by dielectric walls. In addition, the integrated circuits may include bipolar junction transistors as well as FETs such as CFETs, NCFETs, CNTFETs, etc.

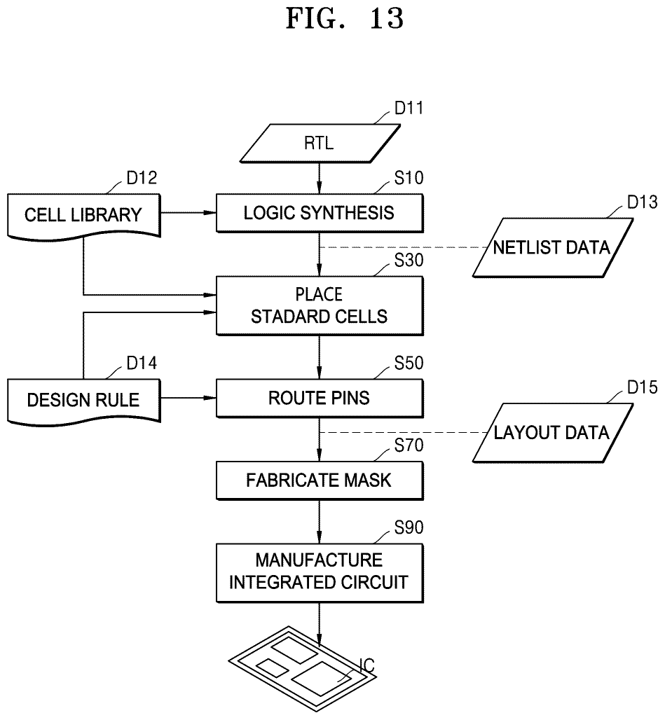

FIG. 13 is a flowchart illustrating an example of a method of manufacturing an integrated circuit.

Referring to FIG. 13, a method is a method of manufacturing an integrated circuit IC including standard cells, and may include a plurality of operations S10, S30, S50, S70, and S90. The cell library (or standard cell library) D12 may include information on standard cells, for example, information on functions, characteristics, layouts, and the like. In some configurations, the cell library D12 may define tap cells and dummy cells as well as functional cells that generate an output signal from an input signal. In some implementations, the cell library D12 may define memory cells and dummy cells having the same footprint. The design rule D14 may include requirements for the layout of the integrated circuit IC to comply. For example, the design rule D14 may include requirements for the space between patterns in the same layer, the minimum width of the pattern, the routing direction of the wiring layer, and the like. In some implementations, the design rule D14 may define a minimum separation distance within the same track of the wiring layer.

In operation S10, a logic synthesis operation for generating netlist data D13 from the RTL data D11 may be performed. For example, semiconductor design tools (e.g., logic synthesis tools) may perform logic synthesis by referring to a cell library D12 from RTL data D11 written with hardware description language (HDL) such as VHSIC Hardware Description Language (VHDL) and Verilog, and may generate netlist data D13 including bitstream or netlist. The netlist data D13 may correspond to an input of place and routing to be described later.

In operation S30, standard cells may be arranged. For example, the semiconductor design tool (e.g., a P&R tool) may arrange standard cells used in the netlist data D13 by referring to the cell library D12. In some implementations, the semiconductor design tool may arrange standard cells in a row extending in the X-axis or Y-axis direction, and the arranged standard cells may receive power from power rails extending along the boundaries of the row.

In operation S50, pins of the standard cells may be routed. For example, the semiconductor design tool may create interconnections that electrically connect the output and input pins of the arranged standard cells, and may create layout data D15 that defines the arranged standard cells and the created interconnections. The interconnection may include vias of the via layer and/or patterns of the wiring layers. The wiring layers may include a frontside wiring layer arranged above the front side of the substrate and a backside wiring layer arranged on the back side of the substrate. The layout data D15 may have a format such as GDSII, for example, and may include geometric information of cells and interconnections. The semiconductor design tool may refer to the design rule D14 while routing the pins of the cells. The layout data D15 may correspond to an output of place and routing. The operation S50 alone, or operations S30 and S50 may collectively be referred to as a method of designing an integrated circuit.

In some implementations, as illustrated in FIGS. 2 to 10B, the integrated circuit may include a backside wiring layer including at least one backside power rail and/or at least one backside signal line. Specifically, a memory cell implemented as a standard cell, for example, a TCAM cell, may receive power such as a power supply voltage or a ground voltage through the backside power rails. In addition, the memory cell implemented as the standard cell, for example, the TCAM cell, may receive an input signal or transfer an output signal via at least one backside signal line. Accordingly, the performance of the integrated circuit may be improved, and the routing freedom of the frontside wiring layer may be improved.

In some implementations, each memory cell MC may receive a supply voltage, e.g., a ground voltage, from a backside power rail arranged on the backside wiring layer through a backside via or DBC. In some implementations, the output node of each memory cell may be connected to the match line ML arranged on the backside wiring layer through a backside via or DBC. In some implementations, each memory cell MC may be connected to a word line WL arranged on the backside wiring layer through a backside via. However, the implementations are not limited thereto, and at least one of signal lines connected to each memory cell MC, for example, bit line BL, complementary bit line BLB, search line SL, complementary search line SLB, match line ML, word line WL, power supply voltage VDD power rail, and ground voltage VSS power rail may be arranged on the backside wiring layer.

In some implementations, each memory cell MC may receive a supply voltage from the backside power rail arranged on the backside wiring layer and output a comparison result through the match line ML arranged on the backside wiring layer. In some implementations, each memory cell MC may receive a supply voltage from the backside power rail arranged on the backside wiring layer and receive a word line signal through the word line WL arranged on the backside wiring layer. In some implementations, each memory cell MC may output a comparison result through the match line ML arranged on the backside wiring layer and receive a word line signal through the word line WL arranged on the backside wiring layer. In some implementations, each memory cell MC may receive a supply voltage from the backside power rail included in the backside wiring layer, output a comparison result through the match line ML arranged in the backside wiring layer, and receive a word line signal through the word line WL arranged in the backside wiring layer.

In operation S70, an operation of fabricating a mask may be performed. For example, optical proximity correction (OPC) for correcting a distortion phenomenon such as refraction due to characteristics of light in photolithography may be applied to layout data D15. Patterns on the mask may be defined to form patterns arranged on a plurality of layers based on data to which the OPC is applied, and at least one mask (or photomask) for forming patterns of each of the plurality of layers may be manufactured. In some implementations, the layout of the integrated circuit IC may be limitedly modified in operation S70, and the limited deformation of the integrated circuit IC in operation S70 may be referred to as design polishing as post-processing for optimizing the structure of the integrated circuit IC.

In operation S90, an operation of manufacturing the integrated circuit IC may be performed. For example, an integrated circuit IC may be manufactured by patterning a plurality of layers using at least one mask manufactured in operation S70. A front-end-of-line (FEOL) may include, for example, planarizing and cleaning a wafer, forming a trench, forming a well, forming a gate line, and forming a source and a drain. By the FEOL, individual devices such as transistors, capacitors, resistors, etc. may be formed on the substrate. In addition, a back-end-of-line (BEOL) may include operations like silicidation of a gate, a source region and a drain region, adding a dielectric, planarizing, forming a hole, adding a metal layer, forming a via, forming a passivation layer, and the like. By the BEOL, individual devices such as transistors, capacitors, resistors, etc. may be interconnected. In some implementations, a middle-of-line (MOL) may be performed between the FEOL and the BEOL, and contacts may be formed on individual devices. Then, the integrated circuit IC may be packaged in a semiconductor package and used as a component for various applications.

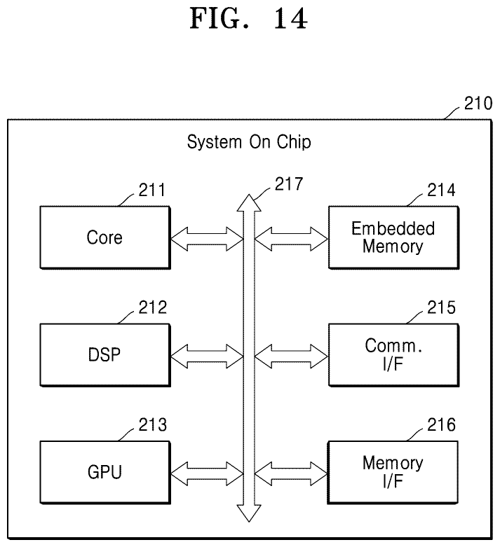

FIG. 14 is a block diagram illustrating an example of a system-on-chip 210.

Referring to FIG. 14, the system-on-chip (SoC) 210 may refer to an integrated circuit in which components of a computing system or other electronic system are integrated. For example, as an example of SoC 210, an application processor (AP) may include components for a processor and other functions. The SoC 210 may include a core 211, a digital signal processor (DSP) 212, a graphics processing unit (GPU) 213, a built-in memory 214, a communication interface 215, and a memory interface 216. The components of the SoC 210 may communicate with each other through a bus 217.

The core 211 may process instructions and control operations of components included in the SoC 210. For example, the core 211 may drive an operating system and execute applications on the operating system by processing a series of instructions. The DSP 212 may generate useful data by processing a digital signal, such as a digital signal provided from the communication interface 215. The GPU 213 may generate data for an image output through the display device from the image data provided from the built-in memory 214 or the memory interface 216, or may encode the image data. In some implementations, the integrated circuit described above with reference to the drawings may be included in the core 211, DSP 212, GPU 213, and/or built-in memory 214.

The built-in memory 214 may store data necessary for the core 211, the DSP 212, and the GPU 213 to operate. The communication interface 215 may provide an interface for a communication network or one-to-one communication. The memory interface 216 may provide an interface for an external memory of the SoC 210, for example, a dynamic random access memory (DRAM), a flash memory, or the like.

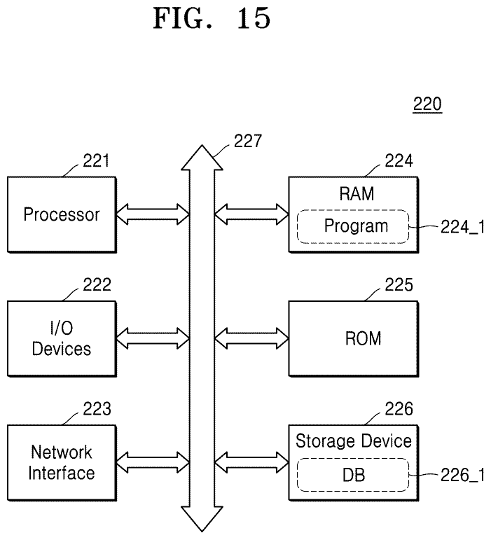

FIG. 15 is a block diagram illustrating an example of a computing system 220 including a memory for storing a program.

Referring to FIG. 15, a method of designing an integrated circuit, for example, at least some of the operations of the flowchart described above may be performed in a computing system (or computer) 220. The computing system 220 may include a processor 22l, input/output devices 222, a network interface 223, a random access memory (RAM) 224, a read only memory (ROM) 225, and a storage device 226. The processor 22l, the input/output devices 222, the network interface 223, the RAM 224, the ROM 225, and the storage device 226 may be connected to a bus 227 and may communicate with each other through the bus 227.

The processor 22l may be referred to as a processing unit, and may include at least one core capable of executing any instruction set (e.g., Intel architecture-32 (IA-32), 64-bit extension IA-32, x86-64, PowerPC, Spark, MIPS, ARM, IA-64, etc.), such as a microprocessor, an AP, a DSP, and a GPU. For example, the processor 22l may access the memory, that is, the RAM 224 or the ROM 225, through the bus 227, and execute instructions stored in the RAM 224 or the ROM 225.

The RAM 224 may store a program 224_1 for a method of designing an integrated circuit or at least a part thereof, and the program 224_1 may allow the processor 22l to perform a method of designing an integrated circuit, for example, at least some of the operations included in the methods of, for example, FIG. 13. That is, the program 224_1 may include a plurality of instructions executable by the processor 22l, and the plurality of instructions included in the program 224_1 may cause the processor 22l to perform at least some of the operations included in the flowcharts described above, for example.

The storage device 226 may not lose stored data even if power supplied to the computing system 220 is cut off. The storage device 226 may store the program 224_1, and the program 224_1 or at least a part thereof may be loaded from the storage device 226 into the RAM 224 before the program 224_1 is executed by the processor 22l . Alternatively, the storage device 226 may store a file written in a program language, and from the file, a program 224_1 generated by a compiler or the like, or at least a part thereof, may be loaded into the RAM 224. In addition, the storage device 226 may store a database 226_1, and the database 226_1 may include information necessary to design an integrated circuit, such as information on designed blocks, the cell library D12 and/or the design rule D14 of FIG. 13.

The storage device 226 may store data to be processed by the processor 22l or data processed by the processor 22l . That is, the processor 22l may generate data by processing the data stored in the storage device 226 according to the program 224_1, and may store the generated data in the storage device 226. For example, the storage device 226 may store the RTL data D11, the netlist data D13, and/or the layout data D15 of FIG. 13.

The input/output devices 222 may include an input device such as a keyboard, a pointing device, or the like, and may include an output device such as a display device, a printer, or the like. For example, a user may trigger execution of the program 224_1 by the processor 22l through the input/output devices 222, input the RTL data D11 and/or the netlist data D13 of FIG. 13, or check the layout data D15 of FIG. 13. The network interface 223 may provide an access to a network outside the computing system 220. For example, the network may include multiple computing systems and communication links, and communication links may include wired links, optical links, wireless links, or any other type of links.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been particularly shown and described with reference to implementations thereof, it will be understood that various changes in form and details may be made therein without departing from the spirit and scope of the following claims.

What is claimed is:

1. An integrated circuit comprising:
a ternary content-addressable memory (TCAM) cell on a front side of a substrate, the TCAM cell including a first cell storing a first value, a second cell storing a second value, and a comparison circuit connected with the first cell and the second cell;
a backside via extending through the substrate in a vertical direction with respect to the substrate;
a backside wiring layer on a back side of the substrate, the backside wiring layer including at least one backside power rail configured to transmit a supply voltage to the TCAM cell through the backside via; and
a frontside wiring layer above the TCAM cell in the vertical direction, the frontside wiring layer including a bit line connected with the first cell and the second cell, a complementary bit line connected with the first cell and the second cell, and a match line connected with the comparison circuit.

2. The integrated circuit of claim 1, wherein
the supply voltage corresponds to a ground voltage, and
the at least one backside power rail is configured to transfer the ground voltage to the TCAM cell through the backside via.

3. The integrated circuit of claim 2, wherein the at least one backside power rail comprises a plurality of backside power rails, the plurality of backside power rails extending in a first direction, the plurality of backside power rails being spaced apart from each other in a second direction, the second direction crossing the first direction.

4. The integrated circuit of claim 2, wherein the frontside wiring layer comprises a frontside power rail configured to transfer a power supply voltage to the TCAM cell.

5. The integrated circuit of claim 1, wherein the frontside wiring layer comprises:
a search line connected with the comparison circuit; and
a complementary search line connected with the comparison circuit, and
wherein the comparison circuit is configured to:
compare search values with the first value and the second value, the search values being input to the search line and the complementary search line; and
output, through the match line, a result of the comparison of the search values with the first value and the second value.

6. The integrated circuit of claim 1, wherein the frontside wiring layer comprises a word line connected with the first cell and the second cell.

7. The integrated circuit of claim 1, wherein
the at least one backside power rail extends in a first direction, and
the frontside wiring layer comprises:
a first frontside wiring layer including the bit line and the complementary bit line, the first frontside wiring layer extending in a second direction, the second direction crossing the first direction; and
a second frontside wiring layer above the first frontside wiring layer in the vertical direction, the second frontside wiring layer including a plurality of word lines and the match line that extend in the first direction.

8. An integrated circuit comprising:
a ternary content-addressable memory (TCAM) cell on a front side of a substrate, the TCAM cell including a first cell storing a first value, a second cell storing a second value, and a comparison circuit connected with the first cell and the second cell;
a backside via extending through the substrate in a vertical direction with respect to the substrate;
a backside wiring layer on a back side of the substrate, the backside wiring layer including a match line connected with the comparison circuit through the backside via; and
a frontside wiring layer above the TCAM cell in the vertical direction, the frontside wiring layer including a bit line connected with the first cell and the second cell, a complementary bit line connected with the first cell and the second cell, and at least one frontside power rail configured to transmit a supply voltage to the TCAM cell.

9. The integrated circuit of claim 8, wherein
the comparison circuit includes a source/drain region corresponding to an output node of the TCAM cell, and
the match line is connected with the source/drain region through the backside via.

10. The integrated circuit of claim 8, wherein
the supply voltage corresponds to a ground voltage, and
the at least one frontside power rail is configured to transfer the ground voltage to the TCAM cell through a via.

11. The integrated circuit of claim 8, wherein
the supply voltage corresponds to a power supply voltage, and
the at least one frontside power rail is configured to transfer the power supply voltage to the TCAM cell through a via.

12. The integrated circuit of claim 8, wherein the frontside wiring layer comprises:
a search line connected with the comparison circuit; and
a complementary search line connected with the comparison circuit, and
wherein the comparison circuit is configured to:
compare search values with the first value and the second value, the search values being input to the search line and the complementary search line; and
output, through the match line, a result of the comparison of the search values with the first value and the second value.

13. The integrated circuit of claim 8, wherein the frontside wiring layer comprises a word line connected with the first cell and the second cell.

14. An integrated circuit comprising:
a ternary content-addressable memory (TCAM) cell on a front side of a substrate, the TCAM cell including a first cell storing a first value, a second cell storing a second value, and a comparison circuit connected with the first cell and the second cell;
a backside via extending through the substrate in a vertical direction with respect to the substrate;
a backside wiring layer on a back side of the substrate, the backside wiring layer including at least one word line connected with the first cell and the second cell through the backside via; and
a frontside wiring layer above the TCAM cell in the vertical direction, the frontside wiring layer including a bit line connected with the first cell and the second cell, a complementary bit line connected with the first cell and the second cell, and at least one frontside power rail configured to transmit a supply voltage to the TCAM cell.

15. The integrated circuit of claim 14, wherein the at least one word line is configured to transfer a word line signal to a gate of a transistor through the backside via, the transistor being included in the first cell or the second cell.

16. The integrated circuit of claim 14, wherein the at least one word line comprises:
a first word line and a second word line, the first word line and the second word line extending in a first direction and spaced apart from each other in a second direction, the second direction crossing the first direction, and
wherein the backside via comprises:
a first backside via on the first word line; and
a second backside via on the second word line, wherein
the first word line is configured to transfer a first word line signal to a gate of a first transistor through the first backside via, the first transistor being included in the first cell, and
the second word line is configured to transfer a second word line signal to a gate of a second transistor through the second backside via, the second transistor being included in the second cell.

17. The integrated circuit of claim 14, wherein
the supply voltage corresponds to a ground voltage, and
the at least one frontside power rail is configured to transfer the ground voltage to the TCAM cell through a via.

18. The integrated circuit of claim 14, wherein
the supply voltage corresponds to a power supply voltage, and
the at least one frontside power rail is configured to transfer the power supply voltage to the TCAM cell through a via.

19. The integrated circuit of claim 14, wherein the frontside wiring layer comprises:
a search line connected with the comparison circuit; and
a complementary search line connected with the comparison circuit, and
wherein the comparison circuit is configured to compare search values with the first value and the second value, the search values being input to the search line and the complementary search line.

20. The integrated circuit of claim 19, wherein the frontside wiring layer comprises:
a match line connected with the comparison circuit, and
wherein the comparison circuit is configured to output a result of the comparison of the search values with the first value and the second value through the match line.
